(19) United States
(12) Patent Application Publication
(10) Pub. No.: US 2019/0198740 A1
(43) Pub. Date: Jun. 27, 2019

(54) THERMOELECTRIC MODULE

(71) Applicant: Mahle International GmbH, Stuttgart (DE)

(72) Inventors: Juergen Gruenwald, Ludwigsburg (DE); Stefan Hirsch, Stuttgart (DE); Volker Schall, Hemmingen (DE); Dominique Weinmann, Rottenburg (DE)

(73) Assignee: Mahle International GmbH, Stuttgart (DE)

(21) Appl. No.: 16/306,551

(22) PCT Filed: Mar. 29, 2017
(86) PCT No.: PCT/EP2017/057448

§ 371 Date: Nov. 30, 2018

(30) Foreign Application Priority Data
Jun. 2, 2016 (DE) 102016209683.4

(51) Int. Cl. H01L 35/10; H01L 35/32; H01L 23/38; H01L 35/30

(52) U.S. Cl. CPC H01L 35/10; H01L 35/30; H01L 23/38; H01L 35/32

(57) ABSTRACT

A thermoelectric module may include a plurality of thermoelectric elements electrically connected via a plurality of conductor bridges. A respective conductor bridge, on at least one of a hot side and a cold side of the thermoelectric module, may contact a duct body through which a fluid is flowable. The duct body may have a plurality of recesses in which, respectively, one of the plurality of conductor bridges is arranged. The plurality of thermoelectric elements may be arranged in a joint thermally insulating filling body. The plurality of conductor bridges may be arranged flush with the filling body. The duct body may have a duct base body and a duct cover closing the duct base body and defining a fluid-tight duct therewith. The duct base body may include a plurality of heat transfer elements protruding into the duct body around which the fluid is flowable.

### CROSS-REFERENCE TO RELATED APPLICATIONS

This application claims priority to International Patent Application No. PCT/EP2017/057448, filed Mar. 29, 2017, and German Patent Application No. DE 10 2016 209 683.4, filed on Jun. 2, 2016, the contents of both of which are hereby incorporated by reference in their entirety.

### TECHNICAL FIELD

The present invention relates to a thermoelectric module comprising a plurality of thermoelectric elements, which are electrically connected by means of conductor bridges. In addition, the invention relates to a thermoelectric generator for recovering power from a temperature difference or a thermoelectric heat pump, respectively, or a thermoelectric cooler for generating heat flows against the natural temperature gradient, which are each equipped with a plurality of such thermoelectric modules.

### BACKGROUND

Thermoelectric modules comprising a plurality of thermoelectric elements are well-known from the prior art. A frequent problem is thereby the optimization of the heat transfer between a hot side and a cold side.

A generic thermoelectric module is known from US 2006/0000500 A1, which has a cooling element on a hot side or cold side, and a closed steam chamber on the respective other side of the thermoelectric module. Electrically non-conductive layers, which serve for the insulation of the flanged cooling element and the steam chamber comprising the conductor bridges, are provided between the thermoelectric module and the cooling element as well as on the other side between the thermoelectric module and the steam chamber.

A generic thermoelectric module comprising a plurality of thermoelectric elements, which are arranged spaced apart from one another, is also known from DE 10 2013 214 988 A1, wherein two thermoelectric elements are in each case electrically connected by means of a conductor bridge, wherein an electrical insulation is arranged at least in some sections on a side of the conductor bridge facing away from the thermoelectric element and/or on a side of the conductor bridge facing the thermoelectric element, wherein the electrical insulation is arranged on the surface of the conductor bridge, wherein the electrical insulation and the conductor bridge are thermomechanically decoupled.

A device for the thermoelectric power generation by means of thermoelectric elements is known from DE 30 32 498 A1, wherein, in an illustrated embodiment, the thermoelectric elements and the respective conductor bridges are in direct contact with a heat transport medium, in particular a dielectric thermal fluid. The thermal fluid flows around the thermoelectric elements and conductor bridges.

A thermoelectric heat exchanger, which allows for a cooling and heating of components, as needed, in particular of high-performance batteries of hybrid and electric vehicles, is known according to DE 10 2012 222 635 A1. The thermoelectric heat exchanger comprises a first component comprising a first duct, a second component comprising a second duct, and a thermoelectric element for generating a heat flow.

### SUMMARY

It is the object of the invention to create an improved embodiment of a thermoelectric module, which realizes an advantageous heat transfer and which can additionally be manufactured more cost-efficiently in particular with regard to the easier production process.

This problem is solved according to the invention by means of the subject matter of the independent claim(s). Advantageous embodiments are the subject matter of the dependent claim(s).

The invention is based on the general idea that in the case of such a thermoelectric module, the respective conductor bridge on the hot side and/or on the cold side of the thermoelectric module is in contact with an electrically insulating, thermally conductive duct body, through which a fluid can flow. A thermal energy, for example starting at the fluid, can be transferred directly to the duct body and further to the conductor bridges by means of the direct contact of the duct body to the conductor bridges on the one hand and to the fluid on the other hand, or the thermal energy can be emitted to the duct body, starting at the conductor bridges, and further to the fluid. The solution according to the invention thus reduces heat transfer losses with simultaneously simplified production and more efficient function. The duct body further serves the purpose of insulation between the current-carrying conductor bridges and the fluid, which thus does not need to have any dielectric properties. The duct body is preferably made of a material with the property of an increased heat conductivity.

In the case of an advantageous further development of the solution according to the invention, the duct body, on a side facing the conductor bridges, has recesses, into which one of these conductor bridges can be inserted in each case. The advantage is that the contact surface, which is relevant for the heat transfer, increases by means of the additional lateral casing of the conductor bridges, through the duct body. With regard to the dimensions, the recesses are advantageously embodied in such a way that a holohedral contact between the duct body and the conductor bridge is established. In other words, the recesses represent an exact negative of a conductor bridge.

The thermoelectric elements are advantageously arranged in a joint thermally insulating filling body. By means of such a thermally insulating filling body, the heat flow is concentrated on contact sides of the thermoelectric elements, which are connected to the conductor bridges. The thermoelectric elements, which are embodied with a for example square cross section, are holohedrally surrounded on their lateral surfaces by the filling body. Advantageously, the filling body is a solid body, which consists for example of a synthetic material or a foam ceramic. The filling body further serves to protect the thermoelectric elements against environmental influences or other media attacks. A further advantageous effect by the filling body is that the thermoelectric elements can be fixedly positioned mechanically and that the thermoelectric modules then have a suitable protection against mechanical, external influences, for example impacts or vibrations. In addition, the filling body serves for an easier assembly of the duct body, which is supported with a side facing the thermoelectric element on such a filling body.

In the case of an advantageous further development, the conductor bridges are flush with the filling body on the hot side and/or the cold side. A front side of the filling body thus lies in one plane with a front side of the conductor bridge. The filling body is thus also in contact with the respective duct body.

In the case of an advantageous further development, a layer of adhesion promoter is present between the conductor bridges and the duct body, wherein the adhesion promotor embodies a tight physical or chemical bond on the boundary surfaces. The conductor bridges, the duct body and the adhesion promoter are thermally coupled. It is further possible to apply a layer of heat transfer promoter between the conductor bridges and the duct body.

In the case of an advantageous further development of the solution according to the invention, the duct body has a duct base body and a duct cover, wherein the duct cover closes the duct base body to form a fluid-tight duct. The duct base body and the duct cover are for example tightly sealed with one another by means of a weld or adhesive connection. The duct base body is to preferably be made as an injection molded part. On principle, a one-piece duct body is possible according to the invention.

It is furthermore advantageous, when heat transfer elements, which protrude into the duct and around which fluid can flow, are arranged on the duct base body, on a side facing away from the conductor bridges. The heat transfer elements are preferably embodied in such a way that the duct cover is supported thereon.

An advantageous embodiment provides that the hot side as well as the cold side are each provided with such a duct body.

An alternative embodiment, in contrast, provides that such a duct body is arranged on the hot side or cold side, while a rib structure or profile structure is arranged on the respective either side.

A thermoelectric generator according to the invention has a plurality of thermoelectric modules of the above-described type, which are electrically connected to one another, wherein the duct bodies of at least two thermoelectric modules are formed by means of sections of a joint duct body.

As does the generator, a thermoelectric heat pump according to the invention or a thermoelectric cooler also has a plurality of thermoelectric modules, which are connected to one another. At least two thermoelectric modules form a joint duct body with their duct body sections.

Further important features and advantages of the invention follow from the subclaims, from the drawings, and from the corresponding figure description by means of the drawings.

It goes without saying that the above-mentioned features and the features, which will be described below, cannot only be used in the respective specified combination, but also in other combinations or alone, without leaving the scope of the present invention.

Preferred exemplary embodiments of the invention are illustrated in the drawings and will be described in more detail in the following description, wherein identical reference numerals refer to identical or similar or functionally identical components.

### BRIEF DESCRIPTION OF THE DRAWINGS

In each case schematically,

FIG. 1 shows an isometric view of a thermoelectric module comprising duct bodies on a hot side as well as on a cold side,

FIG. 2 shows an isometric view of a plurality of thermoelectric elements of the module arranged in one plane,

FIG. 3 shows the isometric view from FIG. 2, which are arranged in a joint thermally insulating filling body,

FIG. 4 shows the isometric view from FIG. 3 comprising attached conductor bridges,

FIG. 5 shows the isometric view from FIG. 4 comprising an attached duct base body,

FIG. 6 shows the isometric view from FIG. 5 comprising an attached duct cover,

FIG. 7 shows a thermoelectric generator or a thermoelectric heat pump, respectively, or a thermoelectric cooler comprising a plurality of thermoelectric modules, which are electrically connected to one another, wherein the duct bodies are formed by a plurality of thermoelectric modules by means of sections of a joint duct body.

### DETAILED DESCRIPTION

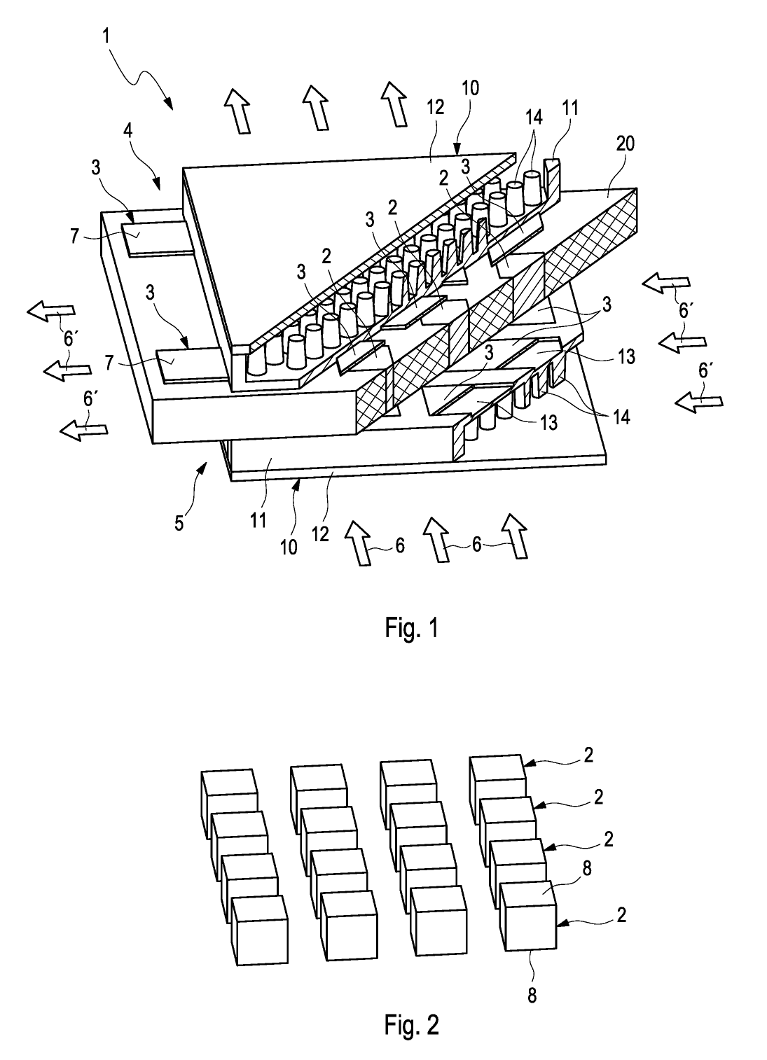

In schematic sectional illustration, FIG. 1 shows an advantageous embodiment of a thermoelectric module 1 according to the invention comprising arranged duct bodies 10 in each case on a hot side 4 as well as on a cold side 5. Thermoelectric elements 2 are arranged spaced apart from one another in one plane. Jointly, the thermoelectric elements 2 are surrounded by a thermally insulating filling body 20. The thermoelectric elements 2 are connected to one another by means of conductor bridges 3. A p-doped and an n-doped thermoelectric element 2 are in each case electrically connected either on the hot side 4 or the cold side 5 in pairs by means of one of the conductor bridges 3.

The filling body 20 is electrically non-conductive and thus insulated the thermoelectric elements 2 from one another on the one hand and the filling body 20 also insulates the conductor bridges 3 of the hot side 4 to the conductor bridges 3 of the cold side 5 on the other hand. The filling body 20 is preferably a solid body of a thermally and electrically non-conductive material, for example of a synthetic material or a foam ceramic.

In this embodiment, the duct bodies 10 are in each case embodied in two pieces comprising a duct base body 11 and a duct cover 12. The duct cover 12 has the object of closing the duct base body 11 to form a fluid-tight duct. On principle, the duct body 10 can be made in one piece for example by means of an extruded material. The object of the duct body 10 is the electrical insulation between the conductor bridges 3 and the fluid 6, 6′ on the one hand, and an advantageous temperature transfer between such conductor bridges 3 and the fluid 6, 6′ on the other hand. The duct body 10 preferably consists of a material comprising a high thermal conductivity, which is electrically insulating. At the locations of the conductor bridges 3, the duct body 10 has recesses 13, in which the conductor bridges 3 can be sunk. Advantageously, the conductor bridges 3 thus do not only transfer the heat orthogonally to the duct body 10, but also via the lateral surfaces of the conductor bridges 3, which are in direct contact with the lateral surfaces of the recesses 13 of the duct body 10. The problem of a hot-spot formation can thus be reduced by increasing the surface for the transfer of the thermal energy.

Heat transfer elements 14 are preferably arranged on a side of the duct base body 11 facing away from the thermoelectric element 2. The heat transfer elements 14 serve for the improved heat transfer between the duct body 10 and a fluid 6, 6′, which is guided through. The heat transfer elements 14, which have a for example circular, cylindrical or truncated cone-shaped cross section, serve, for example simultaneously, as bearing surface for the duct cover 12, which, in addition to the lateral walls of the duct base body 11, is supported on the front sides of the heat transfer elements 14. The duct cover 12 can also be fastened to the heat transfer elements 14. In the alternative, the heat transfer elements 14 can also be embodied to be rib-shaped, nub-shaped or lamella-shaped in an exemplary manner, wherein any molding is on principle possible for the heat transfer. Such heat transfer elements 14 are preferably molded integrally on the duct body 10. The fluid 6, 6′, which flows through the duct, can be liquid or gaseous, for example a coolant or a heating medium. When flowing through the duct body 10, the fluid 6 is heated on the hot side 4, wherein the fluid 6′ is cooled on the cold side 5 in response to flowing through the duct body 10. FIGS. 2 to 6 show the structural setup of the above-described thermoelectric module 2 from FIG. 1 in a schematic manner.

FIG. 2 shows a plurality of thermoelectric elements 2 in a schematic manner, which are arranged spaced apart from one another in one plane. Pairs of p-doped and n-doped thermoelectric elements 2 are thereby always formed, which are also referred to as Peltier element. The thermoelectric elements 2 have a thermoelectrically active material.

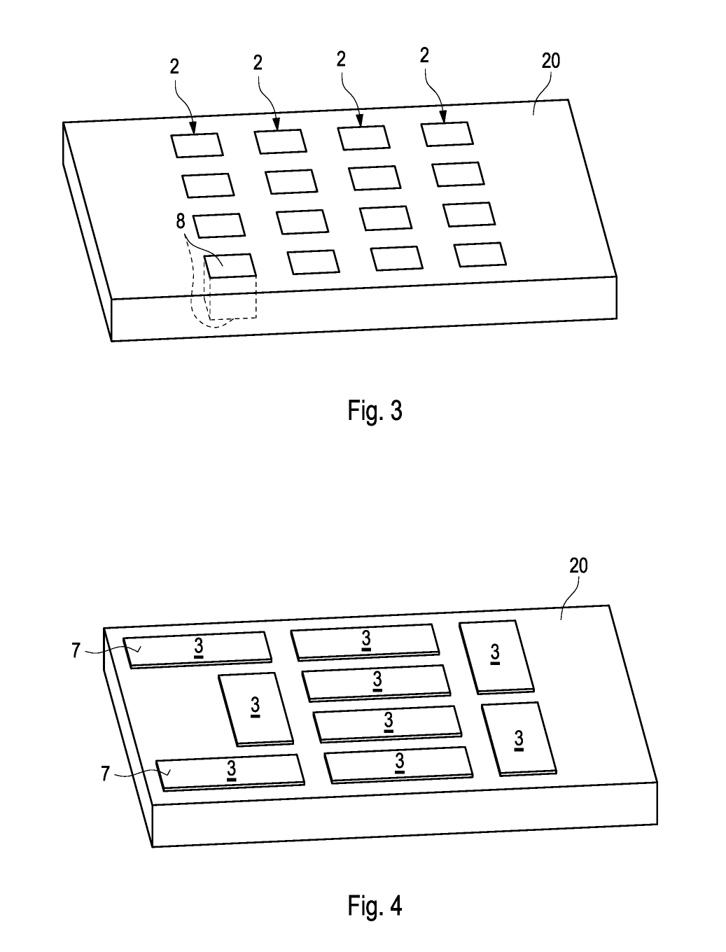

FIG. 3 shows thermoelectric elements 2 are arranged next to one another, which are arranged spaced apart from one another and in one plane, and which are surrounded by such a filling body 20. The filling body 20 concentrates the heat flow to contact sides 8 of the thermoelectric elements 2. On their lateral surfaces, the thermoelectric elements 2 are holohedrally surrounded by the filling body 20.

FIG. 4 shows the conductor bridges 3 in a schematic manner, which a p-doped and an n-doped thermoelectric element 2 electrically connects to one another in each case. In the illustration, the electrical connection by means of the conductor bridges 3 takes place for example in a series connection, in the case of which a p-doped thermoelectric element 2 is in each case alternately connected to an n-doped one on the hot side 4 and on the cold side 5. An advantageous embodiment provides that the conductor bridges 3 are flush with the filling body 20 on the hot side 4 and/or on the cold side 5. The conductor bridges 3 and the filling body 20 lie in one plane on the respective front sides.

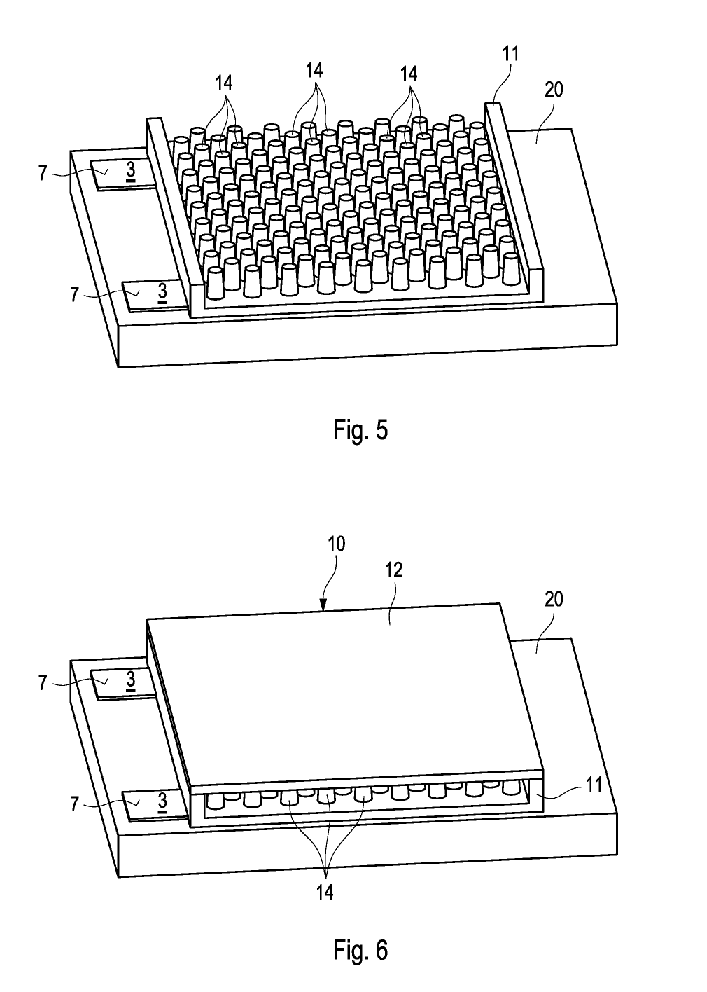

FIG. 5 shows the attached duct base body 11, which is supported on the conductor bridges 3 and the filling body 20. The duct base body 11 encases the conductor bridges 3 almost completely, only two contact surfaces 7 of two conductor bridges 3 are exposed for connection to a power source or in response to the use as a thermoelectric generator 100 on the power generator. Advantageously, a layer of adhesion promoter can be arranged between the conductor bridges 3 and the duct body 10. It is further possible to apply a layer of heat transfer promoter between the conductor bridges 3 and the duct body 10.

FIG. 6 shows such a fluid-tight duct, which is formed by attaching the duct cover 12 onto the duct base body 12. In the case of the two-piece embodiment of the duct body 10, for example the duct cover 12 can consist of a different material than the duct base body 11.

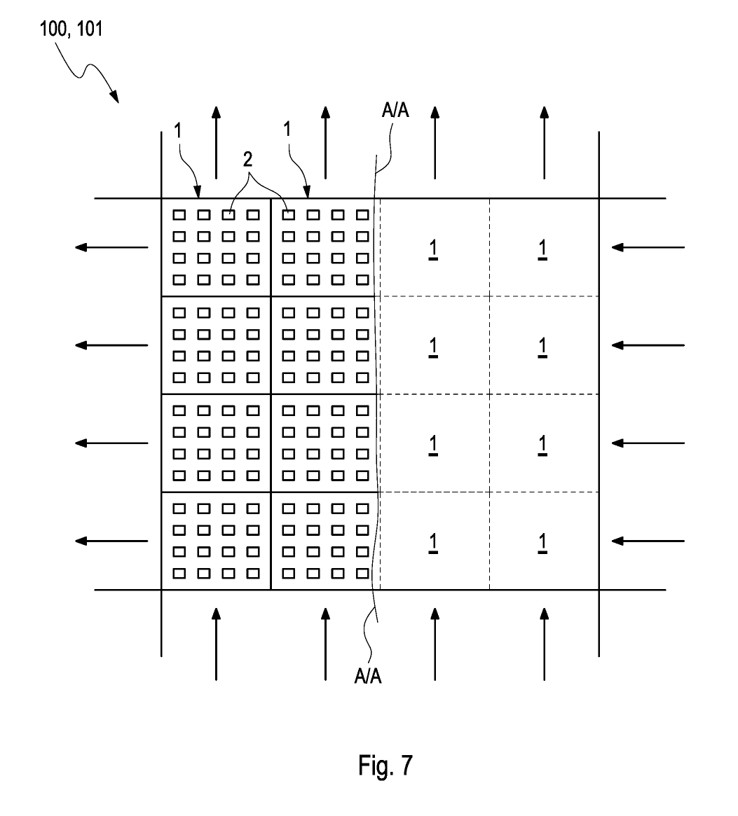

FIG. 7 shows a thermoelectric generator 100 or a thermoelectric heat pump, respectively, or a thermoelectric cooler 101 in a schematic manner, which consist of a plurality of the above-described thermoelectric modules. In the section A-A, it can be seen that the modules 1 have a modular property and can thus be assembled in any number. The individual thermoelectric modules are electrically connected to one another. In the case of the embodiment as a thermoelectric generator 100 or as a thermoelectric heat pump, respectively, or a thermoelectric cooler 101, the contact surfaces 7 advantageously do not protrude at the thermoelectric modules 1. In fact, the contact surfaces 7 are flush with the thermoelectric modules 1 per se.

When the modules 1 in the generator 100 or in the heat pump, respectively, or in the cooler 101 are used as separate units comprising separate duct bodies 10, the separate duct bodies 10 combine in the flow direction of the fluid 6, 6′, which is guided therein, to form a joint duct, which advantageously extends across all modules 1 on the hot side 4 or cold side 5, respectively. When a plurality of modules 1 is arranged next to one another transversely to the flow direction of the fluid 6, 6′, as in the shown example, a plurality of such joint ducts then result, which lie next to one another and which run parallel to one another. In the alternative, it can be provided in the case of a preferred embodiment that at least in the case of two modules 1, which are arranged one behind the other on the hot side 4 or on the cold side 5 with respect to the respective flow direction of the fluid 6, 6′, the corresponding duct bodies 10 each form a longitudinal section of a continuous joint duct body. Advantageously, this joint duct body extends across all modules 1 of the generator 100 or of the heat pump, respectively, or of the cooler 101 in the flow direction of the fluid 6, 6′, which is guided therein. If, as in the shown example, a plurality of modules 1 is arranged next to one another transversely to the flow direction, the joint duct body can optionally also extend across at least two, preferably across all modules 1. In the extreme case, a single joint duct body, which extends across all modules 1 of the generator 100 or of the heat pump, respectively, or of the cooler 101, can thus be provided on the hot side 4 or on the cold side 5, respectively.

1.-13. (canceled)

14. A thermoelectric module comprising a plurality of thermoelectric elements electrically connected via a plurality of conductor bridges, wherein:
a respective conductor bridge of the plurality of conductor bridges, on at least one of a hot side and a cold side of the thermoelectric module, is in contact with an electrically insulating, thermally conductive duct body through which a fluid is flowable;
the duct body, on a side facing the plurality of conductor bridges, has a plurality of recesses in which, respectively, one of the plurality of conductor bridges is arranged;
the plurality of thermoelectric elements are arranged in a joint thermally insulating filling body;
the plurality of conductor bridges are arranged flush with the filling body on at least one of the hot side and the cold side;
the duct body has a duct base body and a duct cover, the duct cover closing the duct base body and defining a fluid-tight duct therewith; and
the duct base body, on a side facing away from the plurality of conductor bridges, includes a plurality of heat transfer elements protruding into the duct body around which the fluid is flowable.

15. The thermoelectric module according to claim 14, further comprising a layer of adhesion promoter disposed between the plurality of conductor bridges and the duct body.

16. The thermoelectric module according to claim 14, wherein the duct base body is an injection molded duct base body.

17. The thermoelectric module according to claim 14, wherein the duct cover is supported on the plurality of heat transfer elements.

18. The thermoelectric module according to claim 14, wherein the duct body is disposed on one of the hot side and the cold side, and another duct body is disposed on the other of the hot side and the cold side.

19. The thermoelectric module according to claim 14, wherein the duct body is arranged on one of the hot side and the cold side, and at least one of a rib structure and a profile structure is arranged on the other of the hot side and the cold side.

20. The thermoelectric module according to claim 19, further comprising a layer of adhesion promoter disposed between the plurality of conductor bridges and the duct body.

21. The thermoelectric module according to claim 19, wherein the duct cover is supported on the plurality of heat transfer elements.

22. A thermoelectric generator comprising a plurality of thermoelectric modules electrically connected to one another, each respective thermoelectric module of the plurality of thermoelectric modules including:
a plurality of thermoelectric elements electrically connected via a plurality of conductor bridges, wherein:
a respective conductor bridge of the plurality of conductor bridges, on at least one of a hot side and a cold of the respective thermoelectric module, contacts an electrically insulating, thermally conductive duct body through which a fluid is flowable;
the duct body, on a side facing the plurality of conductor bridges, has a plurality of recesses in which, respectively, one of the plurality of conductor bridges is arranged;
the plurality of thermoelectric elements are arranged in a joint thermally insulating filling body;
the plurality of conductor bridges are arranged flush with the filling body on at least one of the hot side and the cold side;
the duct body has a duct base body and a duct cover, the duct cover closing the duct base body and defining a fluid-tight duct therewith; and
the duct base body, on a side facing away from the plurality of conductor bridges, includes a plurality of heat transfer elements protruding into the duct body around which the fluid is flowable;
wherein a respective duct body of at least two thermoelectric modules of the plurality of thermoelectric modules is defined by a section of a joint duct body.

23. The thermoelectric generator according to claim 22, further comprising a layer of adhesion promoter disposed between the plurality of conductor bridges and the duct body.

24. The thermoelectric generator according to claim 22, wherein the duct base body is an injection molded duct base body.

25. The thermoelectric generator according to claim 22, wherein the duct cover is supported on the plurality of heat transfer elements.

26. The thermoelectric generator according to claim 22, wherein the duct body is disposed on one of the hot side and the cold side, and another duct body is disposed on the other of the hot side and the cold side.

27. The thermoelectric generator according to claim 22, wherein the duct body is arranged on one of the hot side and the cold side, and at least one of a rib structure and a profile structure is arranged on the other of the hot side and the cold side.

28. A thermoelectric heat pump or thermoelectric cooler comprising a plurality of thermoelectric modules electrically connected to one another, each respective thermoelectric module of the plurality of thermoelectric modules including:
a plurality of thermoelectric elements electrically connected via a plurality of conductor bridges, wherein:
a respective conductor bridge of the plurality of conductor bridges, on at least one of a hot side and a cold of the respective thermoelectric module, contacts an electrically insulating, thermally conductive duct body through which a fluid is flowable;
the duct body, on a side facing the plurality of conductor bridges, has a plurality of recesses in which, respectively, one of the plurality of conductor bridges is arranged;
the plurality of thermoelectric elements are arranged in a joint thermally insulating filling body;
the plurality of conductor bridges are arranged flush with the filling body on at least one of the hot side and the cold side;
the duct body has a duct base body and a duct cover, the duct cover closing the duct base body and defining a fluid-tight duct therewith; and
the duct base body, on a side facing away from the plurality of conductor bridges, includes a plurality of heat transfer elements protruding into the duct body around which the fluid is flowable;
wherein a respective duct body of at least two thermoelectric modules of the plurality of thermoelectric modules is defined by a section of a joint duct body.

29. The thermoelectric heat pump or thermoelectric cooler according to claim 28, further comprising a layer of adhesion promoter disposed between the plurality of conductor bridges and the duct body.

30. The thermoelectric heat pump or thermoelectric cooler according to claim 28, wherein the duct base body is an injection molded duct base body.

31. The thermoelectric heat pump or thermoelectric cooler according to claim 28, wherein the duct cover is supported on the plurality of heat transfer elements.

32. The thermoelectric heat pump or thermoelectric cooler according to claim 28, wherein the duct body is disposed on one of the hot side and the cold side, and another duct body is disposed on the other of the hot side and the cold side.

33. The thermoelectric heat pump or thermoelectric cooler according to claim 28, wherein the duct body is arranged on one of the hot side and the cold side, and at least one of a rib structure and a profile structure is arranged on the other of the hot side and the cold side.
